(19) United States
(12) Patent Application Publication
(10) Pub. No.: US 2024/0361408 A1
(43) Pub. Date: Oct. 31, 2024

(54) SYSTEM AND METHOD FOR MR IMAGING USING PULSE SEQUENCES OPTIMIZED USING A SYSTEMATIC ERROR INDEX TO CHARACTERIZE ARTIFACTS

(71) Applicant: Case Western Reserve University, Cleveland, OH (US)

(72) Inventors: Siyuan Hu, Cleveland, OH (US); Dan Ma, Solon, OH (US)

(21) Appl. No.: 18/649,018

(22) Filed: Apr. 29, 2024

Related U.S. Application Data
(60) Provisional application No. 63/499,125, filed on Apr. 28, 2023.

(51) Int. Cl. G01R 33/54

(52) U.S. Cl. CPC G01R 33/543

(57) ABSTRACT

A method for generating magnetic resonance (MR) images using a magnetic resonance imaging (MRI) system includes determining an optimized set of sequence parameters for a pulse sequence using an optimization framework comprising a systematic error index (SEI) configured to characterize errors, performing, using the MRI system, the pulse sequence comprising the optimized set of sequence parameters to acquire data from a subject, and generating at least one image of the subject using the acquired data.

### CROSS-REFERENCE TO RELATED APPLICATIONS

This application is based on, claims priority to, and incorporates herein by reference in its entirety U.S. Application No. 63/499, 125 filed Apr. 28, 2023, and entitled “System And Method For MR Imaging Using Pulse Sequences Optimized Using A Systematic Error Index to Characterize Artifacts.”

### STATEMENT REGARDING FEDERALLY SPONSORED RESEARCH

This invention was made with government support under NS109439 and CA269604 awarded by the National Institutes of Health. The government has certain rights in the invention.

### BACKGROUND

Characterizing tissue species using nuclear magnetic resonance (“NMR”) can include identifying different properties of a resonant species (e.g., T₁ spin-lattice relaxation, T₂ spin-spin relaxation, proton density). Other properties like tissue types and super-position of attributes can also be identified using NMR signals. These properties and others may be identified simultaneously using magnetic resonance fingerprinting (“MRF”), which is described, as one example, by D. Ma, et al., in “Magnetic Resonance Fingerprinting,” Nature, 2013; 495 (7440): 187-192.

Conventional magnetic resonance imaging (“MRI”) pulse sequences include repetitive similar preparation phases, waiting phases, and acquisition phases that serially produce signals from which images can be made. The preparation phase determines when a signal can be acquired and determines the properties of the acquired signal. For example, a first pulse sequence may produce a T₁-weighted signal at a first echo time (“TE”), while a second pulse sequence may produce a T₂-weighted signal at a second TE. These conventional pulse sequences typically provide qualitative results where data are acquired with various weighting or contrasts that highlight a particular parameter (e.g., T₁ relaxation, T₂ relaxation).

When magnetic resonance (“MR”) images are generated, they may be viewed by a radiologist and/or surgeon who interprets the qualitative images for specific disease signatures. The radiologist may examine multiple image types (e.g., T₁-weighted, T₂-weighted) acquired in multiple imaging planes to make a diagnosis. The radiologist or other individual examining the qualitative images may need particular skill to be able to assess changes from session to session, from machine to machine, and from machine configuration to machine configuration.

Unlike conventional MRI, MRF employs a series of varied sequence blocks that simultaneously produce different signal evolutions in different resonant species (e.g., tissues) to which the radio frequency (“RF”) is applied. The signals from different resonant tissues will, however, be different and can be distinguished using MRF. The signals over a period of time can be collected to obtain a signal evolution in the volume. Resonant species in the volume can then be characterized by comparing the signal evolution to known signal evolutions. Characterizing the resonant species may include identifying a material or tissue type, or may include identifying MR parameters associated with the resonant species. The “known” evolutions may be, for example, simulated evolutions calculated from physical principles and/or previously acquired evolutions. A large set of known evolutions may be stored in a dictionary.

In accelerated MRF scans, usually a portion of the frequency spectrum of the signal is acquired at each time frame, leading to quantification errors of MR parameters. Appropriate pulse sequence design can improve the measurement accuracy of MRF scans without compensating the scan efficiency. To design robust MRF pulse sequences, it is critical to characterize the dominating errors in the highly-undersampled MRF signals, including systematic errors due to undersampling, background phase, and field inhomogeneities. Since the systematic errors spatially depend on the image structure and sampling masks and temporally depend on the signal evolution, there is no exquisite analytical solution to describe the systematic errors. Prior methods to optimize MRF sequence design have used simulations to characterize, estimate and minimize the systematic errors in a physics-inspired optimization framework. A partially separable approach was utilized to generate undersampled image series in the simulations. The resulting quantitative errors of T₁ and T₂ maps were then obtained from dictionary matching and used in a cost function. However, such a framework requires the simulation of a full dictionary and pattern matching with all possible T₁ and T₂ combinations to evaluate quantification errors from every candidate sequence during optimization. It is thus challenging to extend this framework to sequence design for higher-dimensional MRF scans where more tissue parameters are quantified, for example, multidimensional MRF (mdMRF) has been developed to quantify relaxation (e.g., T₁, T₂) and diffusion (e.g., ADC) simultaneously, and MRF with quadratic RF phase (qRF-MRF) has been developed to quantify an additional relaxation property T₂* along with T₁ and T₂. The extra dimensions increase the size of the dictionary exponentially and makes characterization of errors by direct simulation computationally expensive and impractical for sequence optimization for scans (e.g., mdMRF, qRF-MRF) with higher dimensions.

### SUMMARY OF THE DISCLOSURE

In accordance with an embodiment, a method for generating magnetic resonance (MR) images using a magnetic resonance imaging (MRI) system includes determining an optimized set of sequence parameters for a pulse sequence using an optimization framework comprising a systematic error index (SEI) configured to characterize errors, performing, using the MRI system, the pulse sequence comprising the optimized set of sequence parameters to acquire data from a subject, and generating at least one image of the subject using the acquired data.

In accordance with another embodiment, a magnetic resonance imaging (MRI) system includes a magnet system configured to generate a polarizing magnetic field about a portion of a subject positioned, a magnetic gradient system including a plurality of magnetic gradient coils configured to apply at least one magnetic gradient field to the polarizing magnetic field, a radio frequency (RF) system configured to apply an RF excitation field to the subject, and to receive magnetic resonance signals from the subject using a coil array, and at least one processor. The at least one process can be configured to determine an optimized set of sequence parameters for a pulse sequence using an optimization framework comprising a systematic error index (SEI) configured to characterize errors, direct the plurality of magnetic gradient coils and the RF system to perform the pulse sequence comprising the optimized set of sequence parameters to acquire data from a subject, and to generate at least one image of the subject using the acquired data.

### BRIEF DESCRIPTION OF THE DRAWINGS

The present invention will hereafter be described with reference to the accompanying drawings, wherein like reference numerals denote like elements.

FIG. 1 is a schematic diagram of an example magnetic resonance imaging (MRI) system in accordance with an embodiment;

FIG. 2 illustrates a method for generating magnetic resonance (MR) images using an optimized pulse sequence generated using an optimization framework comprising a systematic error index (SEI) in accordance with an embodiment;

FIG. 3 illustrates an example method for magnetic resonance fingerprinting (MRF) in accordance with an embodiment;

FIG. 4 illustrates a comparison of errors generated using an SEI method with the quantitative errors generated from a direct simulation method for example MRF and mdMRF sequences in accordance with an embodiment;

FIGS. 5A and 5B show example simulation results and sequence patterns of example optimized sequences of MRF as compared to a human designed MRF sequence in accordance with an embodiment;

FIG. 6 shows a comparison of in vivo performance of multiple example MRF sequences optimized using a SEI-based method and multiple human-designed MRF sequences in accordance with an embodiment;

FIGS. 7A and 7B show example simulation results and sequence patterns of example optimized sequences of mdMRF as compared to a human designed mdMRF sequence in accordance with an embodiment;

FIG. 8 shows a comparison of example in vivo performance of multiple example mdMRF sequences optimized using a SEI-based method and a human-designed mdMRF sequence in accordance with an embodiment; and

FIG. 9 is a block diagram of an example computer system in accordance with an embodiment.

### DETAILED DESCRIPTION

Magnetic resonance fingerprinting (“MRF”) is a technique that facilitates mapping of tissue or other material properties based on random or pseudorandom measurements of the subject or object being imaged. In particular, MRF can be conceptualized as evolutions in different “resonant species” to which the RF is applied. The term “resonant species,” as used herein, refers to a material, such as water, fat, bone, muscle, soft tissue, and the like, that can be made to resonate using NMR. By way of illustration, when radio frequency (“RF”) energy is applied to a volume that has both bone and muscle tissue, then both the bone and muscle tissue will produce a nuclear magnetic resonance (“NMR”) signal; however, the “bone signal” represents a first resonant species and the “muscle signal” represents a second resonant species, and thus the two signals will be different. These different signals from different species can be collected simultaneously over a period of time to collect an overall “signal evolution” for the volume.

The measurements obtained in MRF techniques are achieved by varying the acquisition parameters from one repetition time (“TR”) period to the next, which creates a time series of signals with varying contrast. Examples of acquisition parameters that can be varied include flip angle (“FA”), RF pulse phase, TR, echo time (“TE’), and sampling patterns, such as by modifying one or more readout encoding gradients. The acquisition parameters are varied in a random manner, pseudorandom manner, or other manner that results in signals from different materials or tissues to be spatially incoherent, temporally incoherent, or both. For example, in some instances, the acquisition parameters can be varied according to a non-random or non-pseudorandom pattern that otherwise results in signals from different materials or tissues to be spatially incoherent, temporally incoherent, or both.

From these measurements, which as mentioned above may be random or pseudorandom, or may contain signals from different materials or tissues that are spatially incoherent, temporally incoherent, or both, MRF processes can be designed to map any of a wide variety of parameters or properties. Examples of such parameters or properties that can be mapped may include, but are not limited to, tissue parameters or properties such as longitudinal relaxation time (T₁), transverse relaxation time (T₂), and proton density (ρ), and device dependent parameters such as main or static magnetic field map (B₀). MRF is generally described in U.S. Pat. No. 8,723,518 and Published U.S. Patent Application No. 2015/0301141, each of which is incorporated herein by reference in its entirety.

The data acquired with MRF techniques are compared with a dictionary of signal models, or templates, that have been generated for different acquisition parameters from magnetic resonance signal models, such as Bloch equation-based physics simulations. This comparison allows estimation of the physical properties, such as those mentioned above. As an example, the comparison of the acquired signals to a dictionary can be performed using any suitable matching or pattern recognition technique. The properties for the tissue or other material in a given voxel are estimated to be the values that provide the best signal template matching. For instance, the comparison of the acquired data with the dictionary can result in the selection of a signal vector, which may constitute a weighted combination of signal vectors, from the dictionary that best corresponds to the observed signal evolution. The selected signal vector includes values for multiple different quantitative properties, which can be extracted from the selected signal vector and used to generate the relevant quantitative property maps.

The stored signals and information derived from reference signal evolutions may be associated with a potentially very large data space. The data space for signal evolutions can be partially described by:

$$SE = {\sum }_{r = 1}^{{N}_{s}} {\prod }_{i = 1}^{{N}_{A}} {\sum }_{j = 1}^{{N}_{RF}} {R}_{i} ( α ) {R}_{{RF}_{ij}} ( α , ∅ ) R ( G ) {E}_{i} ( {T}_{I} , {T}_{2} , D ) {M}_{0} \qquad ( 1 )$$

where SE is a signal evolution; N_{S} is a number of spins; N_{A} is a number of sequence blocks; N_{RF} is a number of RF pulses in a sequence block; α is a flip angle; ϕ is a phase angle; Rᵢ(α) is a rotation due to off resonance; R_{RF}_{ᵢⱼ}(α, ϕ) is a rotation due to RF differences; R(G) is a rotation due to a magnetic field gradient; T₁ is a longitudinal, or spin-lattice, relaxation time; T₂ is a transverse, or spin-spin, relaxation time; D is diffusion relaxation; Eᵢ(T₁,T₂, D) is a signal decay due to relaxation differences; and M₀ is the magnetization in the default or natural alignment to which spins align when placed in the main magnetic field.

While Eᵢ(T₁,T₂, D) is provided as an example, in different situations, the decay term, Eᵢ(T₁,T₂, D), may also include additional terms, Eᵢ(T₁,T₂, D, . . . ) or may include fewer terms, such as by not including the diffusion relaxation, as Eᵢ(T₁,T₂) or Eᵢ(T₁,T₂, . . . ). Also, the summation on “j” could be replace by a product on “j”. The dictionary may store signals described by,

$${S}_{i} = {R}_{i} {E}_{i} ( {S}_{i - 1} ) \qquad ( 2 )$$

where S₀ is the default, or equilibrium, magnetization; Sᵢ is a vector that represents the different components of magnetization, Mₓ, M_{y}, and M_{z} during the i^{th} acquisition block; Rᵢ is a combination of rotational effects that occur during the i^{th} acquisition block; and Eᵢ is a combination of effects that alter the amount of magnetization in the different states for the i^{th} acquisition block. In this situation, the signal at the i^{th} acquisition block is a function of the previous signal at acquisition block (i.e., the (i−1)^{th} acquisition block). Additionally or alternatively, the dictionary may store signals as a function of the current relaxation and rotation effects and of previous acquisitions. Additionally or alternatively, the dictionary may store signals such that voxels have multiple resonant species or spins, and the effects may be different for every spin within a voxel. Further still, the dictionary may store signals such that voxels may have multiple resonant species or spins, and the effects may be different for spins within a voxel, and thus the signal may be a function of the effects and the previous acquisition blocks.

Thus, in MRF, a unique signal timecourse is generated for each pixel. This timecourse evolves based on both physiological tissue properties such as T₁ or T₂ as well as acquisition parameters like flip angle (FA) and repetition time (TR). This signal timecourse can, thus, be referred to as a signal evolution and each pixel can be matched to an entry in the dictionary, which is a collection of possible signal evolutions or timecourses calculated using a range of possible tissue property values and knowledge of the quantum physics that govern the signal evolution. Upon matching the measured signal evolution/timecourse to a specific dictionary entry, the tissue properties corresponding to that dictionary entry can be identified. A fundamental criterion in MRF is that spatial incoherence be maintained to help separate signals that are mixed due to undersampling. In other words, signals from various locations should differ from each other, in order to be able to separate them when aliased.

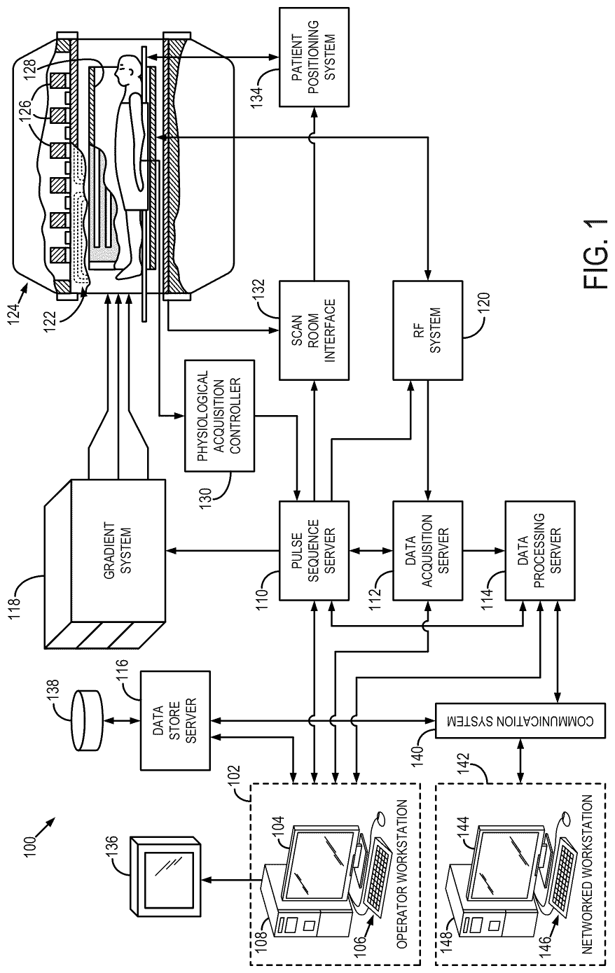

To achieve this process, a magnetic resonance imaging (MRI) system or nuclear magnetic resonance (NMR) system may be utilized. FIG. 1 shows an example of an MRI system 100 that may be used to perform magnetic resonance fingerprinting. In addition, MRI system 100 may be used to implement the methods described herein. MRI system 100 includes an operator workstation 102, which may include a display 104, one or more input devices 106 (e.g., a keyboard, a mouse), and a processor 108. The processor 108 may include a commercially available programmable machine running a commercially available operating system. The operator workstation 102 provides an operator interface that facilitates entering scan parameters into the MRI system 100. The operator workstation 102 may be coupled to different servers, including, for example, a pulse sequence server 110, a data acquisition server 112, a data processing server 114, and a data store server 116. The operator workstation 102 and the servers 110, 112, 114, and 116 may be connected via a communication system 140, which may include wired or wireless network connections.

The pulse sequence server 110 functions in response to instructions provided by the operator workstation 102 to operate a gradient system 118 and a radiofrequency (“RF”) system 120. Gradient waveforms for performing a prescribed scan are produced and applied to the gradient system 118, which then excites gradient coils in an assembly 122 to produce the magnetic field gradients Gₓ, G_{y}, and G_{z} that are used for spatially encoding magnetic resonance signals. The gradient coil assembly 122 forms part of a magnet assembly 124 that includes a polarizing magnet 126 and a whole-body RF coil 128.

RF waveforms are applied by the RF system 120 to the RF coil 128, or a separate local coil to perform the prescribed magnetic resonance pulse sequence. Responsive magnetic resonance signals detected by the RF coil 128, or a separate local coil, are received by the RF system 120. The responsive magnetic resonance signals may be amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the prescribed scan and direction from the pulse sequence server 110 to produce RF pulses of the desired frequency, phase, and pulse amplitude waveform. The generated RF pulses may be applied to the whole-body RF coil 128 or to one or more local coils or coil arrays.

The RF system 120 also includes one or more RF receiver channels. An RF receiver channel includes an RF preamplifier that amplifies the magnetic resonance signal received by the coil 128 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} \qquad ( 3 )$$

and the phase of the received magnetic resonance signal may also be determined according to the following relationship:

$$φ = {tan}^{- 1} ( \frac{Q}{I} ) \qquad ( 4 )$$

The pulse sequence server 110 may receive patient data from a physiological acquisition controller 130. By way of example, the physiological acquisition controller 130 may receive signals from a number of different sensors connected to the patient, including electrocardiograph (“ECG”) signals from electrodes, or respiratory signals from a respiratory bellows or other respiratory monitoring devices. These signals may be used by the pulse sequence server 110 to synchronize, or “gate,” the performance of the scan with the subject's heartbeat or respiration.

The pulse sequence server 110 may also connect to a scan room interface circuit 132 that receives signals from various sensors associated with the condition of the patient and the magnet system. Through the scan room interface circuit 132, a patient positioning system 134 can receive commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, so that data is not lost by data overrun. In some scans, the data acquisition server 112 passes the acquired magnetic resonance data to the data processor server 114. In scans that require information derived from acquired magnetic resonance data to control the further performance of the scan, the data acquisition server 112 may be programmed to produce such information and convey it to the pulse sequence server 110. For example, during pre-scans, magnetic resonance data may be acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also process magnetic resonance signals used to detect the arrival of a contrast agent in a magnetic resonance angiography (“MRA”) scan. For example, the data acquisition server 112 may acquire magnetic resonance data and processes it in real-time to produce information that is used to control the scan.

The data processing server 114 receives magnetic resonance data from the data acquisition server 112 and processes the magnetic resonance data in accordance with instructions provided by the operator workstation 102. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 114 are conveyed back to the operator workstation 102 for storage. Real-time images may be stored in a data base memory cache, from which they may be output to operator display 102 or a display 136. Batch mode images or selected real time images may be stored in a host database on disc storage 138. When such images have been reconstructed and transferred to storage, the data processing server 114 may notify the data store server 116 on the operator workstation 102. The operator workstation 102 may be used by an operator to archive the images, produce films, or send the images via a network to other facilities.

The MRI system 100 may also include one or more networked workstations 142. For example, a networked workstation 142 may include a display 144, one or more input devices 146 (e.g., a keyboard, a mouse), and a processor 148. The networked workstation 142 may be located within the same facility as the operator workstation 102, or in a different facility, such as a different healthcare institution or clinic.

The networked workstation 142 may gain remote access to the data processing server 114 or data store server 116 via the communication system 140. Accordingly, multiple networked workstations 142 may have access to the data processing server 114 and the data store server 116. In this manner, magnetic resonance data, reconstructed images, or other data may be exchanged between the data processing server 114 or the data store server 116 and the networked workstations 142, such that the data or images may be remotely processed by a networked workstation 142.

The present disclosure describes systems and methods for generating an optimized magnetic resonance pulse sequence using an optimization framework that utilizes a Systematic Error Index (SEI), a model to characterize systematic errors with high computational efficiency, in a cost function used to generate optimized sequence parameters for the pulse sequence. The pulse sequence can be, for example, an MRF pulse sequence, a multi-dimensional MRF (mdMRF) pulse sequence, an MRF with quadratic RF phase (qRF-MRF) pulse sequence, a CEST (chemical exchange saturation transfer)-MRF pulse sequence, an MRF-ASL (arterial spin labeling pulse sequence, other multi-dimensional MRF pulse sequences, or other types of multi-dimensional (or multi-parametric) quantitative MR pulse sequences (e.g., quantitative sequences that also employ dictionary matching for quantitative mapping). In some embodiments, the optimized pulse sequence (e.g., MRF or mdMRF or qRF-MRF, etc.) can be performed on an MRI system to acquire data (e.g., MR or MRF data) which can be used to generate images (e.g., MR or MRF images) and/or determine quantitative parameters of a region of interest (e.g., a tissue on a region of interest) of a subject. Advantagcously, the optimization framework with an SEI model can have an accelerated calculation speed compared to direct simulation methods for error characterization (e.g., methods that include dictionary matching with all dictionary entries to evaluate quantification errors). Pulse sequences (e.g., MRF, mdMRF, qRF-MRF, other multi-dimensional sequences) optimized using the SEI-based optimization framework can advantageously produce accurate tissue property maps at shorter scan times compared to human-designed sequences (or scans). In addition, in some embodiments optimized sequences (or scans) generated with the SEI-based model can allow for and be used with simplified reconstruction procedures, thereby enhancing the overall effectiveness and applicability of, for example, MRF-based scans. In some embodiments, optimized pulse sequences generated with the SEI-based model can be used with advanced reconstruction methods, for example, low-rank iterative reconstruction, to further enhance scan performance.

The disclosed Systematic Error Index (SEI) is a fast error characterization model that 1) can account for the undersampling artifacts from arbitrary trajectories and field inhomogencity, and 2) can be handled by currently available computational power for sequence optimization of MRF, mdMRF, qRF-MRF and other sequences. Unlike previous models used to characterize errors, the disclosed SEI-based error characterization model does not require the generation of a sequence specific database (e.g., a dictionary) to quantify the measurement errors. When the measurement dimension (e.g., the number of tissue properties) of, for example, MRF sequences increases, the computational time of the previous models grows exponentially due to the exponentially growing database; the computational time of the disclosed SEI-based model increases linearly as a comparison. In some embodiments, the disclosed SEI-based model can be used to approximate errors both qualitatively and quantitatively, for example, the SEI can replicate the spatial pattern error qualitatively and approximate the error magnitude quantitatively. In some embodiments, for optimization (e.g., sequence parameter optimization) of a basic MRF pulse sequence that enables 2-dimensional (2D) tissue property measurements (e.g., T₁ and T₂), the disclosed SEI-based model can achieve 100× fold acceleration as compared to the previous model in computational speed. In some embodiments, in cases of optimization (e.g., sequence parameter optimization) of an MRF pulse sequence that enables three-dimensional (3D) tissue property measurements (e.g., T₁. T₂. ADC), 1000× fold acceleration could be achieved with the disclosed SEI-based model. While the following description may be discussed in terms of 2- and 3-dimensional tissue properties or parameters, it should be understood that the systems and methods disclosed herein may be used for pulse sequences used to measure more than three tissue properties or parameters.

The disclosed SEI-based fast error characterization model can be used for optimization schemes to design pulse sequences such as, for example, MRF, mdMRF, qRF-MRF scans, with shorter scan time and improved robustness against measurement errors, such as, for example, undersampling, BO inhomogeneity, and system imperfections. In some embodiments, the SEI-based model may be extended to include more error sources, such as random noise, in the signal model. In some embodiments, the disclosed optimization technique is not limited to MRF but can also enable design for any other high-dimensional quantitative imaging framework. While the following description may be discussed in terms of optimization of example MRF and mdMRF sequences, it should be understood that, as mentioned, the disclosed SEI-based optimization method can be for optimization of other multi-dimensional MRF pulse sequences or other types of multi-dimensional (or multi-parametric) quantitative MR pulse sequences.

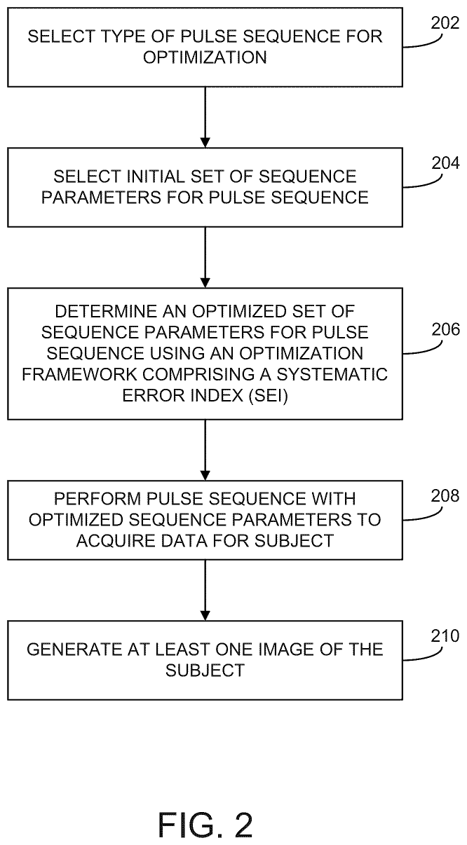

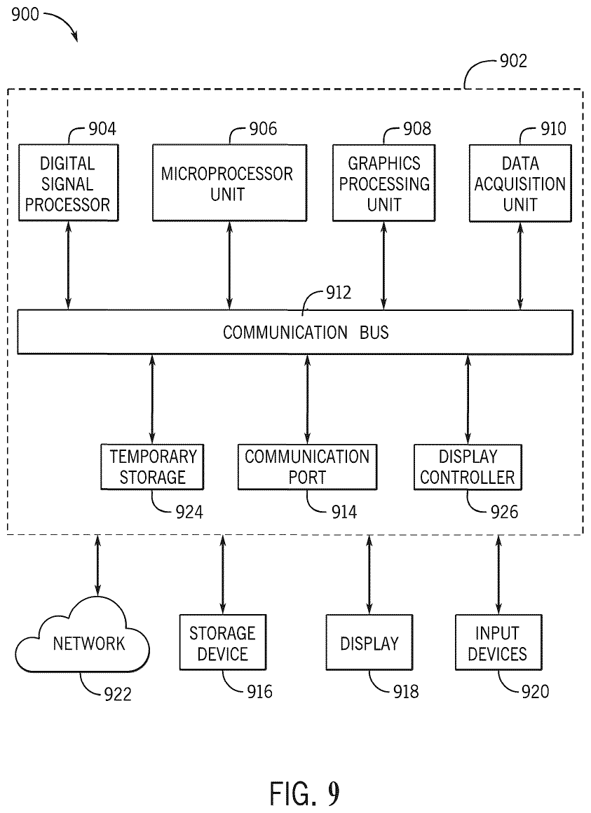

FIG. 2 illustrates a method for generating magnetic resonance (MR) images using an optimized pulse sequence generated using an optimization framework comprising a systematic error index (SEI) in accordance with an embodiment. Although the blocks of the process of FIG. 2 are illustrated in a particular order, in some embodiments, one or more blocks may be executed in a different order than illustrated in FIG. 2, or may be bypassed. At block 202, a type of pulse sequence can be selected for optimization. For example, a user or operator may select the type of pulse sequence using an input device of an operator workstation of an MRI system (e.g., input devices 106 of operator workstation 102 of the MRI system 100 shown in FIG. 1) or an input device of a computer system (e.g., input devices 920 of computer system 900 shown in FIG. 9). The selected pulse sequence can be, for example, an MRF pulse sequence, a multi-dimensional MRF (mdMRF) pulse sequence, an MRF with quadratic RF phase (qRF-MRF) pulse sequence, a CEST (chemical exchange saturation transfer)-MRF pulse sequence, an MRF-ASL (arterial spin labeling pulse sequence, other multi-dimensional MRF pulse sequences, or other types of multi-dimensional (or multi-parametric) quantitative MR pulse sequences (e.g., quantitative sequences that also employ dictionary matching for quantitative mapping). In some embodiments, the selected pulse sequence can be configured to enable generation of images or maps and/or quantification of two or more tissue properties. In one example, a conventional MRF sequence can enable measurements of T₁ and T₂. In another example, an mdMRF pulse sequence can be configured to, for example, simultaneously quantify relaxation and diffusion parameters and properties, such as, for example, T₁, T₂, diffusivity or diffusion tensor, and proton density. In some embodiments, the diffusivity or diffusion tensor may be used to measure quantitative parameters such as, for example, apparent diffusion coefficient (ADC), fractional anisotropy (FA), microscopic anisotropy (μFA), or other microstructure-related parameters. In yet another example, a qRF-MRF pulse sequence can be configured to quantify T₁, T₂, T₂*, and off-resonance.

At block 204, an initial set of sequence parameters for the pulse sequence can be selected. For example, a user or operator may select an initial set of sequence parameters or the initial set of sequence parameters can be randomly generated (e.g., random seeds). In some embodiments, the initial set of sequence parameters can be retrieved from memory or data storage of, for example, an MRI system (e.g., MRI system 100 shown in FIG. 1) or other computer systems.

At block 206, an optimized set of sequence parameters can be determined using an optimization framework comprising a systematic error index (SEI). In some embodiments, the goal of optimizing the sequence design can be to minimize quantification errors. Based on the pattern matching algorithm that can be adopted in MRF for quantitative mapping, minimized quantification errors (or accurate quantification) can be achieved when the inner product between the normalized acquired signal ŝ and its corresponding normalized dictionary entry \hat{d}(θ) is maximized, for example:

$$max \vert 〈 \hat{s} , \hat{d} ( θ ) 〉 \vert \qquad ( 5 )$$

where θ is a set of two or more tissue properties to be measured using the pulse sequence, ŝ is a vector denoting the normalized acquired signal, and \hat{d}(θ) is a vector denoting the normalized dictionary signal, which can be computed based on ground truth tissue property values. In one example, for a conventional MRF sequence the measured tissue properties can be T₁ and T₂ (i.e., θ∈{T₁, T₂} in Equation 5). In another example, for an mdMRF sequence the measured tissue properties can be T₁, T₂, and ADC (i.e., θ∈{T₁, T₂, ADC} in Equation 5). In yet another example, for a qRF-MRF sequence, the measured tissue properties can be T₁, T₂, T₂*, and off-resonance (i.e., θ∈{T₁, T₂, T₂*, off−resonace}.

The maximization problem in Equation 5 is equivalent to minimizing the first-order derivatives of the normalized inner product with respect to the tissue properties, θ, for the pulse sequence, for example, T₁, T₂, and ADC for an example mdMRF sequence. Lower derivative values (e.g., closer to zero) indicate lower matching errors (i.e., quantification errors). The SEI for each tissue property measurement, θ, can be calculated by summing the first-order derivatives across all pixels, P:

$$SEI ( θ ) = \frac{1}{P} \vert \frac{\partial \vert {f}_{p} ( θ ) \vert}{\partial θ} \vert \qquad ( 6 )$$

$$with$$

$${f}_{p} ( θ ) = \frac{〈 {s}_{p} , {d}_{p} ( θ ) 〉}{‖ {s}_{p} ‖ ‖ {d}_{p} ( θ ) ‖}$$

where sₚ is a vector denoting the acquired signal at pixel p, dₚ(θ) is a vector denoting the ground truth signal of pixel p, which can be computed using ground truth tissue property values of the pixel.

In some embodiments, the optimization framework can include simulating acquired signals/images using the candidate pulse sequence and parameters selected at block 204 and a numerical phantom (e.g., a segmented numerical phantom) for the region of interest. The numerical phantom can include, for example, a number of representative tissue types, the predetermined tissue type(s) for each pixel, predetermined tissue property values (e.g., ground truth tissue property values) for each pixel, and a partial volume fraction of each tissue type on each pixel. In some embodiments, the numerical phantom can include a finite number of homogeneous tissue types of interest. In some embodiments, simulated acquired signals from a virtual scan for an accelerated pulse sequence (e.g., MRF, mdMRF, etc.) can be represented using a partially separable approach to efficiently simulate the effect of undersampling and field inhomogeneities. Given a numerical phantom that consists of a number of representative tissue types, i, the dictionary entry (or ground truth signal) at a pixel P can be given by:

$${d}_{p} ( θ ) = {\sum }_{i}^{Tissue} {M}_{i} ( p ) {d}_{i} ( θ ) \qquad ( 7 )$$

where Mᵢ is a matrix, Mᵢ(p) denotes the partial volume fraction (ranging from 0 to 1) of tissue type i at pixel p on the numerical phantom, dᵢ(θ) is a vector denoting the ground truth signal of tissue type i, which is dependent upon tissue property values θ, dₚ(θ) is a vector denoting the final ground truth signal of pixel p, which depends on tissue property values θ. In some embodiments, the ground truth signal for each tissue type i, dᵢ(θ), can be derived using the Bloch equations, the pulse sequence parameters, and predetermined (or ground truth) tissue property values for the tissue type, for example, from the numerical phantom. Advantageously, for the disclosed optimization framework, a tissue type ground truth signal dᵢ(θ) only needs to be determined for each of tissue types (i) included in the numerical phantom, for example, three tissue type ground truth signal would be determined for a numerical phantom including three tissue types. The simulated acquired signal at a pixel P can be given by:

$${s}_{p} = {\sum }_{i}^{Tissue} {Ψ}_{i} ( p ) {d}_{i} ( θ ) \qquad ( 8 )$$

$$with$$

$${Ψ}_{i} = {F}_{us}^{- I} {KF}_{full} {M}_{i} ( p ) {e}^{i φ ( p )}$$

where Ψᵢ is a matrix denoting the spatial response function, i.e. undersampled partial fraction map, for tissue type i, Fᵤₛ and F_{full} are the undersampled and full-sampled NUFFT (Non-uniform Fast Fourier Transform) operators, K is the undersampling mask in the frequency domain, and φ(p) is the background phase due to B0 inhomogeneity. In some embodiments, the values for Fᵤₛ, F_{full}, K and the background phase φ(p) can be fixed predefined values. Once the acquired signals/images have been simulated (e.g., using the sequence parameters of the pulse sequence and the numerical phantom using Equation 8). The SEI for each tissue property measurement (θ) can then be calculated based on the simulated acquired signals, sₚ, and the ground truth signals, dₚ(θ), for each pixel.

The SEI value is arbitrary, making it difficult to evaluate and relate to the actual errors in measurement (e.g., quantification) of the tissue properties (e.g., T₁. T₂, ADC for a mdMRF sequence). Moreover, low SEI values do not imply accurate matching without information about the curvature of inner products fₚ(θ_{dict}), where θ_{dict} is a vector denoting all the tissue property combinations used to compute a dictionary, and fₚ(θ_{dict}) is a vector of the same length with θ_{dict}, whose entries are calculated following Equation 6 using corresponding tissue property values in θ_{dict}. Therefore, in some embodiments, 1) the local curvature (or local steepness) of the inner product curve fₚ(θ_{dict}) can be approximated using, for example, a parabola model (e.g., y=k(x−xₘₐₓ)²+yₘₐₓ), and 2) the SEI can be linearly scaled with the parabola coefficients. The scaling can allow the first-order derivatives of the inner products to align in magnitude with the actual mapping errors. A nearby point fₚ(θ±Δθ) on the inner product curve can be used to calculate the parabola coefficient kₚ for each pixel. Thus, a scaled SEI (percentage error) can be calculated as:

$$SEI ( θ ) = \frac{1}{p} {\sum }_{p}^{P} \frac{\vert \frac{\partial \vert {f}_{p} ( θ ) \vert}{\partial θ} / \frac{1}{P} {\sum }_{p}^{r} \vert {k}_{p} \vert \vert}{θ} \qquad ( 9 )$$

where the SEI incudes summing the first-order derivatives across all pixels, P. In SEI formulations, the spatial basis functions, Ψᵢ(p) and Mᵢ(p), are independent of sequence parameters and, in some embodiments, can be precomputed during optimization; therefore, the remaining components to be updated are dᵢ(θ), ∂dᵢ(θ)/∂θ, and dᵢ(θ±Δθ). For example, for a three dimensional mdMRF sequence and a numerical phantom with three tissue types, a total of 21 signals (i.e., three ground truth tissue type signals (dᵢ(θ)), and a dᵢ(θ±Δθ) signal for all tissue types and all measurement dimensions (3×3×2=18) and 9 signal derivatives (i.e., a signal derivative, ∂dᵢ(θ)/∂θ, for all tissue types across all tissue type dimensions (3×3=9)) may be determined for each optimization iteration. In comparison, dictionaries consisting of tens of thousands of entries would need to be generated and pattern matching is required in prior direct simulation methods for optimization. Advantageously, the SEI model can significantly accelerate the estimation of a cost function for optimization of high-dimensional sequences, making sequence optimization practical. In some embodiments, the optimization framework can utilize the scaled SEI (e.g., as given by Equation 9). Accordingly, the SEI for each tissue property measurement (θ) can be calculated using Equation 9.

As mentioned above, the SEI (e.g., the scaled SEI as given in Equation 9) can be used to optimize a pulse sequence, for example, MRF, mdMRF, qRF-MRF, or other high-dimensional quantitative MR sequences. In some embodiments, the cost functions for optimization can advantageously be constructed as:

$$min {\sum }_{θ} SEI ( θ ) \qquad ( 10 )$$

where θ is a set of two or more tissue properties to be measured using the pulse sequence. In one example, for a conventional MRF sequence the measured tissue properties can be T₁ and T₂ (i.e., θ∈{T₁, T₂} in Equation 10). In another example, for an mdMRF sequence the measured tissue properties can be T₁, T₂, and ADC (i.e., θ∈{T₁, T₂, ADC} in Equation 10). In yet another example, for a qRF-MRF sequence the measured tissue properties can be T₁, T₂, T₂*, and off-resonance (i.e., θ∈{T₁, T₂, T₂*, off−resonace} in Equation 10. In some embodiments, as indicated by the cost function in equation 10, the optimized sequence parameters can be determined by minimizing the SEI. In some embodiments, the optimization of the SEI-based cost function can be performed using optimization methods such as, for example, a simulated annealing method, other stochastic optimization algorithms, sequential quadratic programming, other quasi-Newton methods, etc. In some embodiments, as discussed above, simulated signals/images (e.g., a time series of images for an MRF-based sequence) can be generated based on a candidate pulse sequence and a numerical phantom (i.e., a numerical scan process), and the SEI (e.g., the scaled SEI given by Equation 9) can be used to determine the systematic errors directly from the simulated signals/images. As mentioned, the simulated images may be generated during the virtual scan process using a numerical phantom for the specific anatomy to be imaged with the resulting optimized pulse sequence. The optimization method or algorithm (e.g., a stochastic optimization algorithm) can be used to determine an optimal solution by iteratively updating the candidate pulse sequences for a fixed number of iterations. In some embodiments, the pulse sequence (and the associated sequence parameters) generated during the optimization process that yields the lowest cost function value can be selected as the final output (i.e., the optimized sequence and sequence parameters) at block 206. In some embodiments, the optimized sequence parameters determined at block 206 may be stored in memory or data storage of, for example, an MRI system (e.g., MRI system 100 shown in FIG. 1) or other computer system.

The specific sequence parameters that are optimized at block 206 can depend on the type of pulse sequence. In one example, the parameters to be optimized for a conventional MRF pulse sequence can include, for example, flip angle and repetition time. In another example, the parameters to be optimized for an mdMRF sequence can include, for example, flip angle, inversion time for T₁ preparations, echo time for T₂ preparations, and b-value for diffusion preparations, and the type of preparation that is inserted in front of the m-th acquisition window. In yet another example, the parameters to be optimized for a qRF-MRF sequence can include, for example, flip angle and RF phase. In some embodiments, additional constraints may be used for the optimization process using the SEI-based cost function, for example, constraints in the form of upper and lower bounds for each sequence parameter to be optimized. In some embodiments, the constraints can be selected to consider physical or hardware limitations such as, for example, specific absorption rate (SAR) of Rf energy. In some embodiments, to improve the optimization results, a parameterization strategy may be used to reduce the dimensionality of the search space for the optimization problem. In some embodiments, time-varying sequence parameters, for example, flip angles (FA) and repetition times (TR), can be represented with cubic splines to reduce the searching dimension. For example, cach spline can be defined by a pair of variables, determining its position in the vertical axis (FA or TR-axis) and the horizonal axis (time frame-axis). High-dimensional pulse sounded (e.g., high-dimensional MRF pulse sequences) can often include additional time-varying parameters (other than FA and TR) that can be specific to the specific sequence design. For example, high-dimensional MRF sequences can include parameters associated with discrete magnetization preparation modules used to enhance signal sensitivity to specific tissue properties. Such parameters can include, for example, inversion times (TI) in T₁ preparation modules, echo times (TE) in T₂ preparation modules, b-values (b) of diffusion preparation modules in mdMRF sequences, mdMRF, number of acquisition time frames within cach acquisition window, and diffusion encoding direction for each diffusion preparation module. In In another example, high dimensional MRF sequences can also include continuous parameters with strong temporal correlation, such as, for example, the RF phase variables in qRF-MRF sequences that varies periodically to create excitation bands sweeping through different on-resonance frequencies. In some embodiments, for a qRF-MRF sequence, the on-resonance sweeping pattern can be parameterized with different numbers of linear functions or higher-order functions.

At block 208, a pulse sequence (e.g., an MRF or mdMRF or qRF-MRF pulse sequence) with the optimized sequence parameters determined at block 206 can be performed using an MRI system (e.g., MRI system 100 shown in FIG. 1) to acquire data (e.g., MRF data) for the subject, for example, MRF data from a region of interest of the subject. In some embodiments, the acquired data may be stored may in memory or data storage of, for example, an MRI system (e.g., MRI system 100 shown in FIG. 1) or other computer system. At block 210, at least one image (e.g., an MRF image) of the subject can be generated using the data acquired at block 206. The image(s) may be generated using known reconstruction techniques. In some embodiments, the at least one generated image may be stored in memory or data storage of, for example, an MRI system (e.g., MRI system 100 shown in FIG. 1) or other computer system.

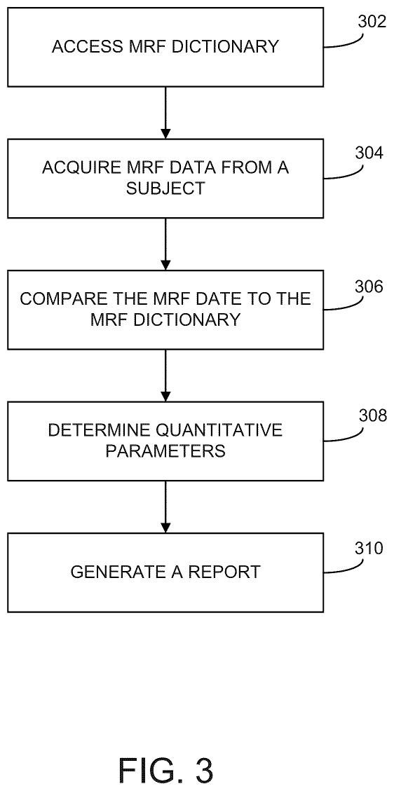

As mentioned above, in some embodiments, the optimized pulse sequence is an MRF-based pulse sequence (e.g., MRF, mdMRF, qRF-MRF, etc.) that may be used to simultaneously determine a plurality of quantitative parameters. FIG. 3 illustrates an example method for magnetic resonance fingerprinting (MRF) in accordance with an embodiment. Although the blocks of the process of FIG. 3 are illustrated in a particular order, in some embodiments, one or more blocks may be executed in a different order than illustrated in FIG. 3, or may be bypassed. At block 302, an MRF dictionary is accessed. The MRF dictionary can include known signal evolutions (e.g., simulated signal evolutions) and can include parameters and properties (e.g., quantitative parameters or property values) associated with each signal evolution, for example, T₁, T₂, T₂*, proton density, off-resonance, diffusivity or diffusion tensor. In some embodiments, the MRF dictionary may be generated using a Bloch simulation or Bloch-Torrey equation. In some embodiments, the MRF dictionary may be stored in memory or data storage of, for example, an MRI system (e.g., MRI system 100 shown in FIG. 1) or other computer system. As used herein, the term “accessing” may refer to any number of activities related to retrieving or processing the MRF dictionary using, for example, MRI system 100 (shown in FIG. 1, an extended network, information repository, or combinations thereof. At block 304, MRF data may be acquired from a subject, for example, from a tissue or region of interest in a subject. The MRF data may be acquired using, for example, an MRI system (e.g., MRI system 100 shown in FIG. 1). Acquiring MRF data may include performing or playing-out a pulse sequence, for example, an optimized MRF or mdMRF pulse sequence generated using the process described above with respect to FIG. 2. In some embodiments, the MRF data may be reconstructed before comparison with the MRF dictionary at block 306 using known reconstruction methods. The acquired MRF data and/or the reconstructed MRF images may be stored in memory or data storage of, for example, an MRI system (e.g., the MRI system 100 of FIG. 1) or other computer system.

The MRF data acquired at block 304 (or the reconstructed MRF images) may be compared to the MRF dictionary at block 306 to match the acquired signal evolutions with signal evolutions stored in the MRF dictionary. “Match” as used herein refers to the result of comparing signals but does not refer to an exact match, which may or may not be found. A match may be the signal evolution that most closely resembles another signal evolution. Comparing the MRF data (or reconstructed images) to the MRF dictionary may be performed in a number of ways such as, for example, using a pattern matching, template matching or other matching algorithm. In some embodiments, dot product pattern matching may be used to select the MRF dictionary entry which most closely fits the acquired signal evolution to extract T₁. T₂, and diffusivity or diffusion tensor for each pixel. In some embodiments, the inner products between the normalized time course of each pixel and all entries of the normalized dictionary are calculated, and the dictionary entry corresponding to the maximum value of the inner product is taken to represent the closest signal evolution to the acquired signal evolution. In some embodiments, iterative pattern matching may be used.

At block 308, one or more quantitative parameters (e.g., relaxation and diffusion parameters) of the MRF data may be determined based on the comparison and matching at block 306. For example, based on the comparison and matching in block 306, the signal evolution (i.e., a dictionary entry) that is determined to be the closest signal evolution (or closest fit) to the acquired signal evolutions may be selected and the parameters associated with the selected dictionary entry assigned to the acquire signal evolutions. The parameters may include, for example, longitudinal relaxation time (T₁), transverse relaxation time (T₂), and diffusivity (ADC) for md-MRF acquisitions. In some embodiments, other parameters may be determined from the comparison and matching, such as, for example, main or static magnetic field (B₀), and proton density. In some embodiments, for an mdMRF acquisition one or more diffusion or diffusivity parameters may be determined using the parameters (e.g., diffusivity or diffusion tensor) determined from the dictionary matching at clock 306. For example, in some embodiments, known methods may be used to determine quantitative parameters for mean diffusivity (MD), apparent diffusion coefficient (ADC), fractional anisotropy (FA), microscopic fractional anisotropy (μFA), or other microstructure related parameters, such as for example, axon diameters, cell density, tissue partial volume, and volume fraction, from the parameters (e.g., diffusivity or diffusion tensor) determined from the dictionary matching at block 306. In an example, the ADC may be calculated by averaging the diffusivity from three diffusion encoding directions. In another example, the fractional anisotropy may be calculated using a known model of axial diffusivity and radial diffusivity. In yet another example, the microscopic fractional anisotropy may be calculated using known methods of diffusivity. In some embodiments, the determined quantitative parameters may be stored in memory or data storage of, for example, an MRI system (e.g., MRI system 100 shown in FIG. 1) or other computer system.

At block 310, a report may be generated indicating at least one of the identified parameters (e.g., relaxation and diffusion parameters) for the tissue in a region of interest in a subject. For example, the report may include a quantitative indication of the at least one parameter. The report may include, for example, images or maps, text or metric based reports, audio reports and the like. The report may be provided to a display (e.g., display 104, 136 or 144 shown in FIG. 1). In some embodiments, the report may be stored in memory or data storage of, for example, an MRI system (e.g., MRI system 100 shown in FIG. 1) or other computer system.

The following examples set forth, in detail, ways in which the present disclosure was evaluated and ways in which the present disclosure may be used or implemented, and will enable one of ordinary skill in the art to more readily understand the principles thereof. The following examples are presented by way of illustration and is not meant to be limiting in any way.

In this example study, the SEI model was validated by comparing the performance of the SEI model to a direct simulation method for error characterization. In addition, the disclosed SEI model, for example, as discussed above with respect to block 206 of FIG. 2 and Equations 9 and 10, was applied to optimize two high-dimensional MRF pulse sequences, MRF and mdMRF, that quantify two and three tissue properties, respectively. The optimized sequences were evaluated using simulations and in vivo experiments. The example study demonstrates accurate and robust in vivo results from the optimized MRF and mdMRF scans obtained from the disclosed SEI-based optimization framework. In this example study, the SEI-based model achieved 100× acceleration in calculation speed compared to the direct simulation method for error characterization. The optimized MRF and mdMRF scans from the SEI-based optimization framework produced accurate tissue property maps at shorter scan times compared to human-designed scans in the vivo experiments.

In this example study, error values generated by the disclosed SEI method were compared with the quantitative T₁, T₂, and ADC errors obtained from a direct simulation method using the same MRF and mdMRF sequences to demonstrates the SEI method is a valid alternative to the direct simulation method. In the example simulation, a digital 3-tissue (white matter (WM), gray matter (GM), and cerebrospinal fluid (CSF)) brain numerical phantom was used to generate a fully-sampled image series with a background phase. The image series were undersampled using a single-shot serial trajectory with an undersampling factor of 48. Undersampled images were then reconstructed into MRF maps via dictionary matching.

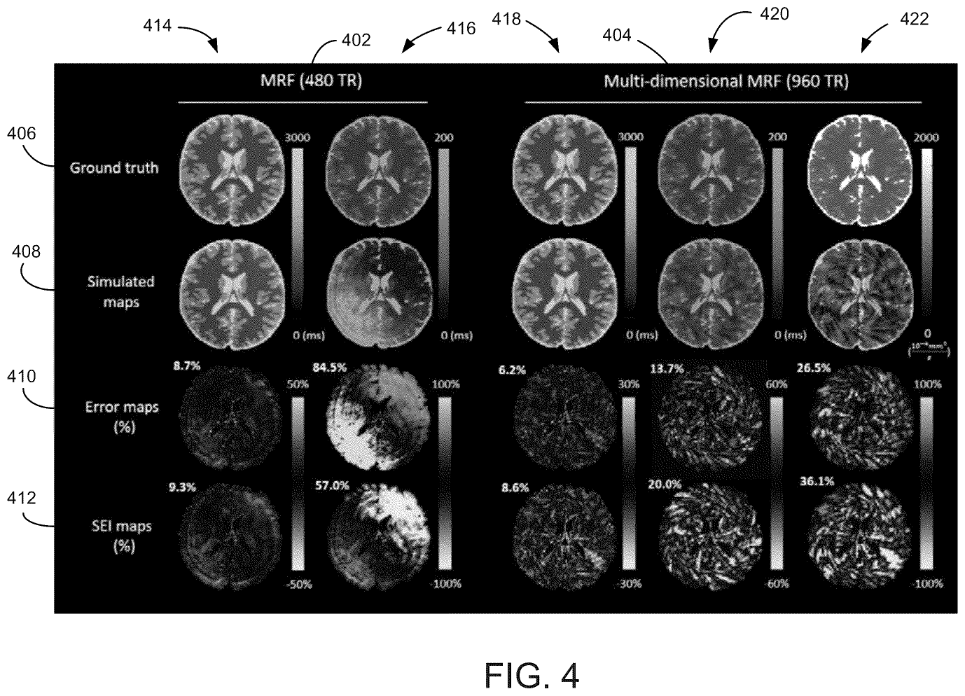

FIG. 4 illustrates a comparison of errors generated using an SEI method with the quantitative errors generated from a direct simulation method for example MRF and mdMRF sequences in accordance with an embodiment. In FIG. 4, results for an example MRF sequence 402 are shown for the tissue properties T₁ (first column 414) and T₂ (second column 416). Results for an example mdMRF sequence 404 are shown for the tissue properties T₁ (third column 418), T₂ (fourth column 420), and ADC (fifth column 422). The first row 406 illustrates ground truth tissue property maps. The second row 408 illustrates example simulated T₁/T₂ maps and T₁/T₂/ADC maps generated using the example MRF sequence and the example mdMRF sequence, respectively. The third row 410 illustrates the corresponding example error maps generated using the direct simulation method for error characterization and the fourth row 412 illustrates the example error maps of scaled SEI values computed on each pixel (e.g., based on Equation 9) using the same MRF and mdMRF sequence as the direct simulation method. In this example study. the SEI maps (percentage error) 412 (fourth row) obtained by calculating the scaled SEI values on each pixel (e.g., using Equation 9) reproduce the artifact patterns on the error maps (percentage error) 410 (third row) from the direct simulation method. The SEI values are also on the same scale with percentage errors. Simulating errors on the digital numerical phantom using the direct simulation method with dictionary generation and matching took 128 seconds for an MRF sequence and 1286 seconds for an mdMRF sequence; the disclosed SEI model took 1.47 seconds and 3.72 seconds as comparisons, which enables efficient error characterizations for sequence optimization. Accordingly, in this example, by reducing the computational times to 10 seconds or less, the disclosed SEI-based method achieved 85-fold and 345-fold acceleration for MRF and mdMRF, respectively. In FIG. 4, the SEI maps 412 approximate the spatial distribution of the artifacts obtained using the direct simulation method and the SEI values 412 have the same order of magnitude as the errors simulated using the direct simulation method 410. The SEI maps 412 successfully replicated the spatial features of systematic errors on the simulated tissue property maps 408 for both the example MRF sequence 402 and the example mdMRF sequence 404. The calculated SEI metrics also can approximate the errors quantitatively.

As mentioned above, in this example study, the disclosed SEI model was applied to optimize two high-dimensional MRF pulse sequences, an MRF sequence and an mdMRF sequence, and the optimized sequences were evaluated using simulations and in vivo experiments. All in vivo scans were performed on healthy volunteers using a 3T scanner. In this example, MRF scans were acquired with matrix size 256×256, FOV 250×250 mm, and processed using NUFFT reconstruction. In this example, mdMRF scans were acquired with matrix size 192×192, FOV 300×300, and reconstructed using a self-calibrated iterative low-rank method. The optimized sequences were repeated 3 times for 3 diffusion encoding directions, and the human-designed sequence was extended to 30 segments to match the length of the in vivo scans.

In this example study, for the MRF sequence optimization, 480 flip angles and 480 TR variables of an MRF-FISP sequence were parameterized using 20 cubic spline indexes respectively, to reduce dimensionality. In this example study, for mdMRF sequence optimization, the mdMRF sequences contain segments of MRF-FISP readouts interrupted by preparation modules. To simultaneously optimize all sequence parameters, the signal model of mdMRF was adapted as described in Hu S., et al. “Optimal experimental design of MR Fingerprinting for simultaneous quantification of T₁, T₂, and ADC, 31st Proc Intl Soc Mag reason Med 2022, herein incorporated by reference in its entirety. In this example study, an mdMRF sequence of 960 TR (10 segments) was optimized with all TR variables being fixed. 960 flip angles were piece-wisely parameterized by 40 cubic spline points (4 points/segment). In this example study, all optimizations were initiated from random seeds and solved by a simulated annealing method.

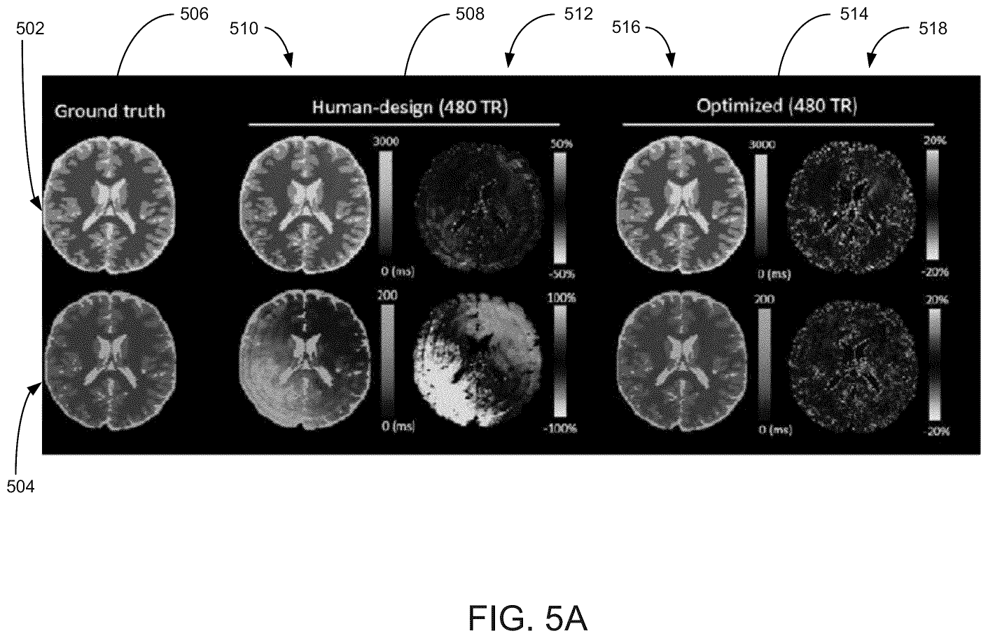

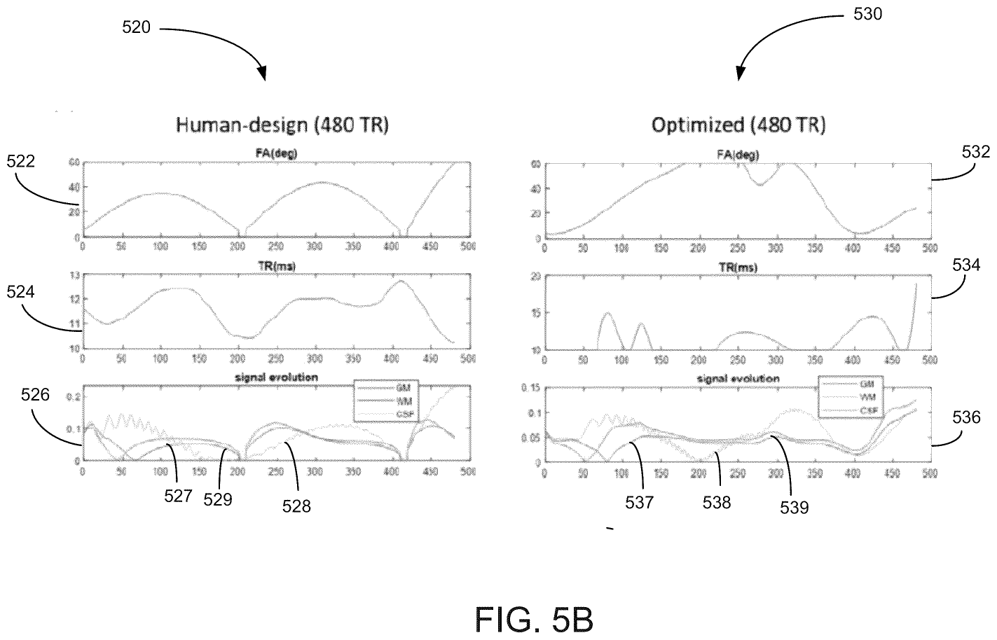

FIGS. 5A and 5B show example simulation results and sequence patterns of example optimized sequences of MRF as compared to a human designed MRF sequence in accordance with an embodiment. In FIG. 5A, the first row 502 shows example tissue property maps and error maps for the tissue property T₁ and the second row 504 shows example tissue property maps and error maps for the tissue property T₂. Example ground truth T₁ and T₂ tissue property maps are shown in the first column 506. Example T₁ and T₂ maps simulated using an example human-designed MRF pulse sequence 508 are shown in the second column 510 and corresponding error maps are shown in the third column 512. Example T₁ and T₂ maps simulated using an example optimized MRF pulse sequence 514 optimized using the disclosed SEI-based method are shown in the fourth column 516 and corresponding error maps are shown in the fifth column 518. In the simulation for this example study, the T₂ map from the human-designed MRF sequence (second row 504, second column 510) shows apparent shading artifacts due to systematic errors; whereas the T₂ map from optimized MRF scan (second row 504, fourth column 516) are not affected by shading artifacts. In FIG. 5B, a sequence pattern 520 for the example human-designed pulse sequence is shown including the flip angle (FA) 522, repetition time (TR) 524, and the signal evolutions 526 for the three tissues in the numerical brain phantom utilized for the simulation in this example, namely, gray matter 527, white matter 528 and cerebrospinal fluid (CSF) 529. FIG. 5B also shows a sequence pattern 520 for the example optimized MRF sequence (as mentioned, optimized using the disclosed SEI-based method) is shown including the flip angle (FA) 532, repetition time (TR) 534, and the signal evolutions 536 for the three tissues in the numerical brain phantom utilized for the simulation in this example, namely, gray matter 537, white matter 538 and cerebrospinal fluid (CSF) 539.

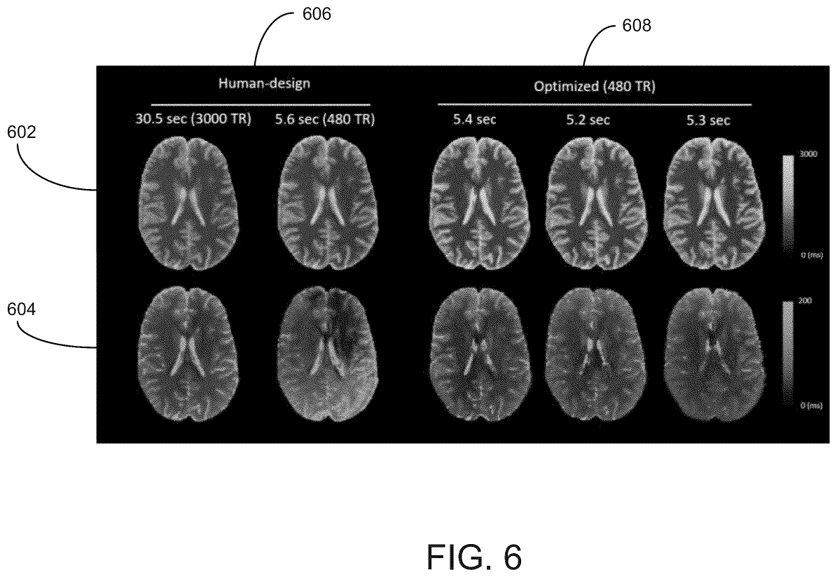

FIG. 6 shows a comparison of in vivo performance of multiple example MRF sequences optimized using a SEI-based method and multiple human-designed MRF sequences in accordance with an embodiment. In FIG. 6, the first row 602 shows example T₁ tissue property maps and the second row 504 shows example T₂ tissue property maps. Example T₁ and T₂ tissue property maps for two example human designed MRF sequences 604 are shown in the first and second column. Example T₁ and T₂ tissue property maps for three example optimized MRF sequences 606 are shown in the third, fourth and fifth columns. The optimized MRF sequences are robust against shading artifacts, especially in T₂, validating the results observed in the simulations. Severe shading artifacts can be observed on T₂ maps from the shortened human-designed scan with 480 TR.

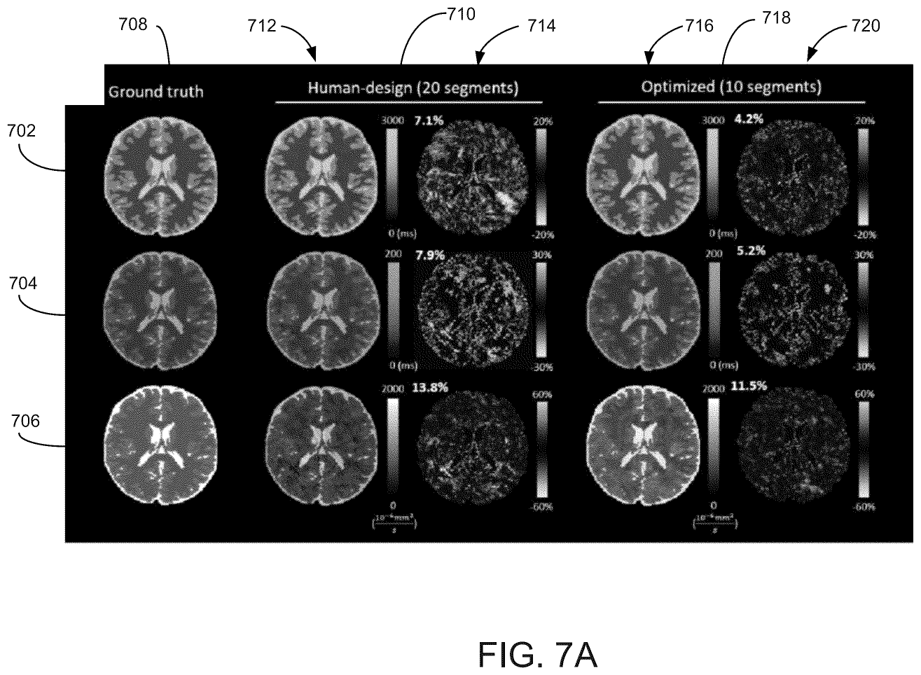

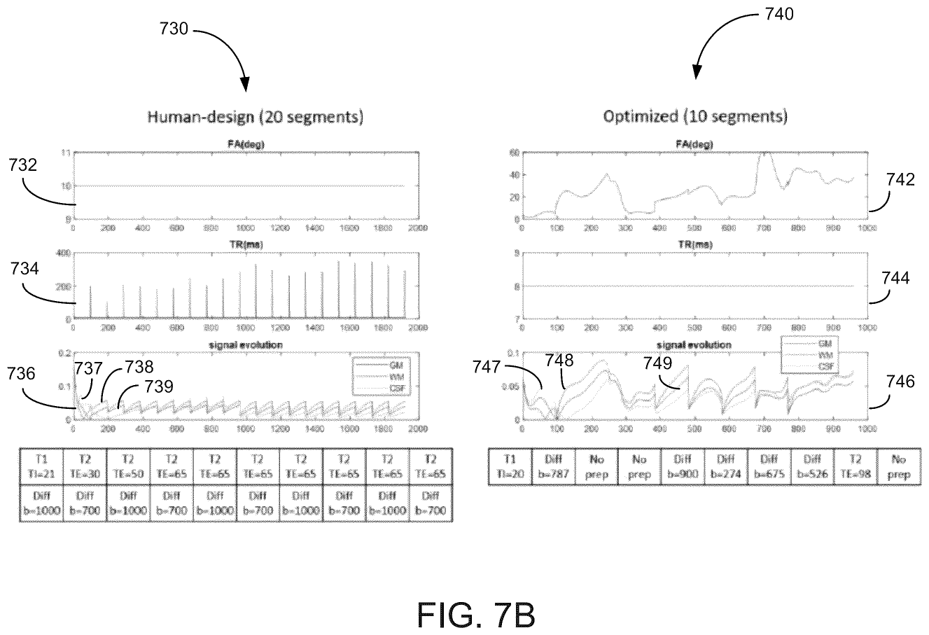

FIGS. 7A and 7B show example simulation results and sequence patterns of example optimized sequences of mdMRF as compared to a human designed mdMRF sequence in accordance with an embodiment. In FIG. 7A, the first row 702 shows example tissue property maps and error maps for the tissue property T₁, the second row 704 shows example tissue property maps and error maps for the tissue property T₂, and the third row shows example tissue property maps and error maps for the tissue property ADC. Example ground truth T₁, T₂, and ADC tissue property maps are shown in the first column 708. Example T₁, T₂, and ADC maps simulated using an example human-designed MRF pulse sequence 710 are shown in the second column 712 and corresponding error maps are shown in the third column 714. Example T₁, T₂, and ADC maps simulated using an example optimized mdMRF pulse sequence 716 optimized using the disclosed SEI-based method are shown in the fourth column 718 and corresponding error maps are shown in the fifth column 720. For mdMRF sequences, the optimized sequence contains 10 segments (8.6 sec), and the human-designed sequence contains 20 segments (21.6 sec) for effective T₂ and diffusion encoding. In this example, since the human-designed pattern begins with 10 non-diffusion prepared segments, it was extended to 20 segments for diffusion encoding. Although the optimized mdMRF sequence is much shorter in length, it yielded higher accuracy for all tissue property measurements. The optimized mdMRF sequence achieved higher robustness against the aliasing artifacts with half of the sequence length as compared to the human design. In FIG. 7B, a sequence pattern 730 for the example human-designed pulse sequence is shown including the flip angle (FA) 732, repetition time (TR) 734, and the signal evolutions 736 for the three tissues in the numerical brain phantom utilized for the simulation in this example, namely, gray matter 737, white matter 738 and cerebrospinal fluid (CSF) 739. FIG. 7B also shows a sequence pattern 740 for the example optimized mdMRF sequence (as mentioned, optimized using the disclosed SEI-based method) is shown including the flip angle (FA) 742, repetition time (TR) 744, and the signal evolutions 746 for the three tissues in the numerical brain phantom utilized for the simulation in this example, namely, gray matter 747, white matter 748 and cerebrospinal fluid (CSF) 749.

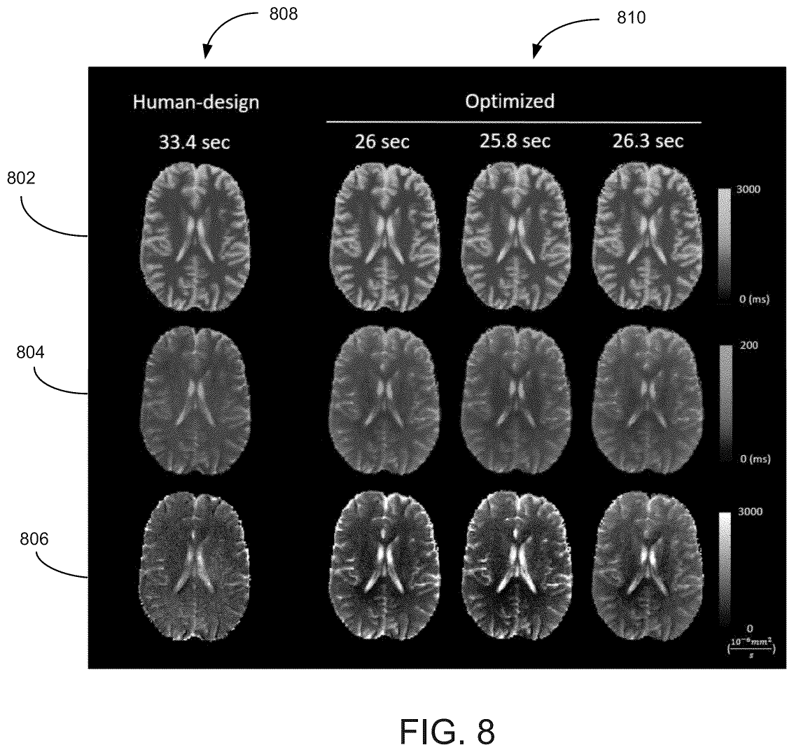

FIG. 8 shows a comparison of example in vivo performance of multiple example mdMRF sequences optimized using a SEI-based method and a human-designed mdMRF sequence in accordance with an embodiment. In FIG. 8, the first row 802 shows example T₁ tissue property maps, the second row 804 shows example T₂ tissue property maps, and the third row 806 shows example ADC tissue property maps. Example T₁, T₂, and ADC tissue property maps for an example human designed mdMRF sequence 808 are shown in the first column. Example T₁, T₂, and ADC tissue property maps for three example optimized mdMRF sequences 810 are shown in the third, fourth and fifth columns. The mdMRF scans from the optimized mdMRF sequences 810 could achieve shorter scan duration with high image quality (e.g., clear contrasts), showing improved contrast on T₂ and ADC maps as compared to the human-designed mdMRF scan 808.

FIG. 9 is a block diagram of an example computer system in accordance with an embodiment. Computer system 900 may be used to implement the systems and methods described herein. In some embodiments, the computer system 900 may be a workstation, a notebook computer, a tablet device, a mobile device, a multimedia device, a network server, a mainframe, one or more controllers, one or more microcontrollers, or any other general-purpose or application-specific computing device. The computer system 900 may operate autonomously or semi-autonomously, or may read executable software instructions from the memory or storage device 916 or a computer-readable medium (e.g., a hard drive, a CD-ROM, flash memory), or may receive instructions via the input device 920 from a user, or any other source logically connected to a computer or device, such as another networked computer or server. Thus, in some embodiments, the computer system 900 can also include any suitable device for reading computer-readable storage media.

Data, such as data acquired with, for example, an imaging system (e.g., a magnetic resonance imaging (MRI) system, etc.), may be provided to the computer system 900 from a data storage device 916, and these data are received in a processing unit 902. In some embodiments, the processing unit 902 included one or more processors. For example, the processing unit 902 may include one or more of a digital signal processor (DSP) 904, a microprocessor unit (MPU) 906, and a graphic processing unit (GPU) 908. The processing unit 902 also includes a data acquisition unit 910 that is configured to electronically receive data to be processed. The DSP 904, MPU 906, GPU 908, and data acquisition unit 910 are all coupled to a communication bus 912. The communication bus 912 may be, for example, a group of wires, or a hardware used for switching data between the peripherals or between any component in the processing unit 902.

The processing unit 902 may also include a communication port 914 in electronic communication with other devices, which may include a storage device 916, a display 918, and one or more input devices 920. Examples of an input device 920 include, but are not limited to, a keyboard, a mouse, and a touch screen through which a user can provide an input. The storage device 916 may be configured to store data, which may include data such as, for example, images of a subject, optimized sequence parameters, quantitative parameters, etc., whether these data are provided to, or processed by, the processing unit 902. The display 918 may be used to display images, reports, and other information, such as patient health data, and so on.

The processing unit 902 can also be in electronic communication with a network 922 to transmit and receive data and other information. The communication port 914 can also be coupled to the processing unit 902 through a switched central resource, for example the communication bus 912. The processing unit 902 can also include temporary storage 924 and a display controller 926. The temporary storage 924 is configured to store temporary information. For example, the temporary storage 924 can be a random-access memory.

Computer-executable instructions for generating an optimized pulse sequence and pulse sequence parameters using an optimization framework comprising a systematic error index (SEI) according to the above-described methods may be stored on a form of computer readable media. Computer readable media includes volatile and nonvolatile, removable, and non-removable media implemented in any method or technology for storage of information such as computer readable instructions, data structures, program modules or other data. Computer readable media includes, but is not limited to, random access memory (RAM), read-only memory (ROM), electrically erasable programmable ROM (EEPROM), flash memory or other memory technology, compact disk ROM (CD-ROM), digital volatile disks (DVD) or other optical storage, magnetic cassettes, magnetic tape, magnetic disk storage or other magnetic storage devices, or any other medium which can be used to store the desired instructions and which may be accessed by a system (e.g., a computer), including by internet or other computer network form of access.

The present invention has been described in terms of one or more preferred embodiments, and it should be appreciated that many equivalents, alternatives, variations, and modifications, aside from those expressly stated, are possible and within the scope of the invention.

1. A method for generating magnetic resonance (MR) images using a magnetic resonance imaging (MRI) system, the method comprising:
determining an optimized set of sequence parameters for a pulse sequence using an optimization framework comprising a systematic error index (SEI) configured to characterize errors;
performing, using the MRI system, the pulse sequence comprising the optimized set of sequence parameters to acquire data from a subject; and
generating at least one image of the subject using the acquired data.

2. The method according to claim 1, wherein the pulse sequence is a multi-dimensional pulse sequence.

3. The method according to claim 1, wherein the pulse sequence is one of a MRF pulse sequence, a multi-dimensional (mdMRF) pulse sequence and a MRF with quadratic RF phase (qRF-MRF) pulse sequence.

4. The method according to claim 1, wherein the systematic error index is given by:
$$SEI ( θ ) = \frac{1}{p} {\sum }_{p}^{P} \frac{\vert \frac{\partial \vert {f}_{p} ( θ ) \vert}{\partial θ} / \frac{1}{P} {\sum }_{p}^{r} \vert {k}_{p} \vert \vert}{θ}$$
$$with$$
$${f}_{p} ( θ ) = \frac{〈 {s}_{p} , {d}_{p} ( θ ) 〉}{‖ {s}_{p} ‖ ‖ {d}_{p} ( θ ) ‖}$$
where θ is a tissue property, p is a pixel, sₚ is a vector denoting the acquired signal at pixel p, dₚ(θ) is a vector denoting the ground truth signal of pixel p, and kₚ is a parabola coefficient for each pixel, p.

5. The method according to claim 4, wherein determining the set of optimized sequence parameters comprises minimizing the systematic error index using a cost function.

6. The method according to claim 5, wherein the cost function is given by:
$$min {\sum }_{θ} SEI ( θ ) .$$

7. The method according to claim 5, wherein the cost function is minimized using a simulated annealing process.

8. The method according to claim 1, wherein the optimized sequence parameters comprise one or more of flip angle, repetition time, inversion time for T₁ preparation, echo time for T₂ preparation, b-value for diffusion preparation, or RF phase.

9. The method according to claim 1, wherein the optimization framework further comprises at least one constraint for at least one of the optimized sequence parameters.

10. A magnetic resonance imaging (MRI) system comprising:
a magnet system configured to generate a polarizing magnetic field about a portion of a subject positioned;
a magnetic gradient system including a plurality of magnetic gradient coils configured to apply at least one magnetic gradient field to the polarizing magnetic field;
a radio frequency (RF) system configured to apply an RF excitation field to the subject, and to receive magnetic resonance signals from the subject sing a coil array; and
at least one processor configured to:
determine an optimized set of sequence parameters for the pulse sequence using an optimization framework comprising a systematic error index (SEI) configured to characterize errors;
direct the plurality of magnetic gradient coils and the RF system to perform the pulse sequence comprising the optimized set of sequence parameters to acquire data from a subject; and
generate at least one image of the subject using the acquired data.

11. The system according to claim 10, wherein the pulse sequence is a multi-dimensional pulse sequence.

12. The system according to claim 10, wherein the pulse sequence is one of a MRF pulse sequence, a multi-dimensional (mdMRF) pulse sequence and a MRF with quadratic RF phase (qRF-MRF) pulse sequence.

13. The system according to claim 10, wherein the systematic error index is given by:
$$SEI ( θ ) = \frac{1}{p} {\sum }_{p}^{P} \frac{\vert \frac{\partial \vert {f}_{p} ( θ ) \vert}{\partial θ} / \frac{1}{P} {\sum }_{p}^{r} \vert {k}_{p} \vert \vert}{θ}$$
$$with$$
$${f}_{p} ( θ ) = \frac{〈 {s}_{p} , {d}_{p} ( θ ) 〉}{‖ {s}_{p} ‖ ‖ {d}_{p} ( θ ) ‖}$$
where θ is a tissue property, p is a pixel, sₚ is a vector denoting the acquired signal at pixel p, dₚ(θ) is a vector denoting the ground truth signal of pixel p, and kₚ is a parabola coefficient for each pixel, p.

14. The system according to claim 13, wherein determining the set of optimized sequence parameters comprises minimizing the systematic error index using a cost function.

15. The system according to claim 14, wherein the cost function is given by:
$$min {\sum }_{θ} SEI ( θ ) .$$

16. The system according to claim 14, wherein the cost function is minimized using a simulated annealing process.

17. The system according to claim 10, wherein the optimized sequence parameters comprise one or more of flip angle, repetition time, inversion time for T₁ preparation, echo time for T₂ preparation, b-value for diffusion preparation, or RF phase.

18. The system according to claim 10, wherein the optimization framework further comprises at least one constraint for at least one of the optimized sequence parameters.
